(19) United States
(12) Patent Application Publication
(10) Pub. No.: US 2023/0119903 A1
(43) Pub. Date: Apr. 20, 2023

(54) MULTILAYER CIRCUIT BOARD AND ELECTRONIC-COMPONENT-EQUIPPED MULTILAYER BOARD

(71) Applicant: Murata Manufacturing Co., Ltd., Nagaokakyo-shi (JP)

(72) Inventors: Takumi MASAKI, Nagaokakyo-shi (JP); Atsushi KISHIMOTO, Nagaokakyo-shi (JP); Masato INAOKA, Nagaokakyo-shi (JP); Takashi SHIMIZU, Nagaokakyo-shi (JP); Hiroshi NISHIKAWA, Nagaokakyo-shi (JP); Takahiro TAKADA, Nagaokakyo-shi (JP)

(21) Appl. No.: 18/085,607

(22) Filed: Dec. 21, 2022

Related U.S. Application Data
(63) Continuation of application No. PCT/JP2021/021501, filed on Jun. 7, 2021.

(30) Foreign Application Priority Data
Jul. 2, 2020 (JP) 2020-114912

(51) Int. Cl. H05K 1/18; H05K 1/02; H05K 1/03; H05K 1/11

(52) U.S. Cl. CPC H05K 1/185; H05K 1/0203; H05K 1/0277; H05K 1/0313; H05K 1/115

(57) ABSTRACT

A multilayer circuit board includes a resin body, signal wires, ground conductors, and a via conductor. The resin body includes resin layers made from thermoplastic resin. The signal wires and the ground conductors are each on or inside the resin body. The via conductor connects corresponding ones of the signal wires to each other or corresponding ones of the ground conductors to each other. The ground conductors include a counter ground conductor on or inside the resin body, facing a signal wire in a stacking direction in which the resin layers are stacked, and overlapping the signal wire in plan view in the stacking direction. The counter ground conductor is made of a graphite sheet including main surfaces and end surfaces covered with a conductor layer. The graphite sheet extends over rigid and flexible portions in plan view in the stacking direction.

### CROSS REFERENCE TO RELATED APPLICATIONS

This application claims the benefit of priority to Japanese Patent Application No. 2020-114912 filed on Jul. 2, 2020 and is a Continuation Application of PCT Application No. PCT/JP2021/021501 filed on Jun. 7, 2021. The entire contents of each application are hereby incorporated herein by reference.

### BACKGROUND OF THE INVENTION

### 1. Field of the Invention

The present invention relates to a multilayer circuit board and an electronic-component-equipped multilayer board.

### 2. Description of the Related Art

Known multilayer circuit boards each include a multilayer body including a stack of a plurality of insulating layers, a plurality of signal wires, and a plurality of ground conductors.

Among such multilayer circuit boards, a resin multilayer board including a stack of a plurality of resin layers serving as insulating layers is typically manufactured by stacking resin sheets. The resin multilayer board includes thereinside conductor patterns and via conductors. The conductor patterns include signal wires and ground conductors each formed from conductive foil pasted on a main surface of any of the resin sheets. The via conductors each extend through any of the resin sheets in the thickness direction and are responsible for electrical connection. Therefore, points of connection between the via conductors and the conductor patterns are present inside the resin multilayer board.

In particular, when a resin multilayer board including flexible resin layers is bent, a bending moment acts on relevant points of connection between the via conductors and the conductor patterns and therefore generates a bending stress. Such a bending stress may deteriorate the state of connection at the above points of connection.

A resin multilayer board disclosed in Japanese Unexamined Patent Application Publication No. 2014-222721 includes a stack of a plurality of resin layers each including a main surface and being made from thermoplastic resin. The resin multilayer board includes a via conductor extending through one of the resin layers in the thickness direction, a conductor pattern provided on the main surface of the resin layer provided with the via conductor, the conductor pattern being connected to the via conductor, and a hard member provided inside the resin multilayer board and having a higher hardness than the resin layers. Seen in a stacking direction in which the plurality of resin layers are stacked, the via conductor is located near the outer edge of the hard member. Seen in the stacking direction, the conductor pattern includes a widened portion whose area increases toward a side away from the hard member.

According to Japanese Unexamined Patent Application Publication No. 2014-222721, since the resin multilayer board includes the widened portion on the side away from the hard member relative to the via conductor, the via conductor is less likely to deform even if a bending stress is generated in the resin multilayer board. Such a configuration is considered to prevent the via conductor and the conductor pattern that are connected to each other from being separated from each other. Thus, the resin multilayer board disclosed in Japanese Unexamined Patent Application Publication No. 2014-222721 provides increased reliability at the points of connection by specifying the shape of the conductor pattern as described above. Instead, the shape of the conductor pattern limits the design of the board.

### SUMMARY OF THE INVENTION

Preferred embodiments of the present invention provide multilayer circuit boards that each obtain a highly reliable connection between via conductors and ground conductors, and electronic-component-equipped multilayer boards in each of which a multilayer circuit board according to a preferred embodiment of the present invention includes an electronic component.

A multilayer circuit board according to a preferred embodiment of the present invention includes a resin body including a stack of a plurality of resin layers each being made from thermoplastic resin, a plurality of signal wires and a plurality of ground conductors each on or inside the resin body, and at least one via conductor extending through at least one of the resin layers in a thickness direction and connecting corresponding ones of the signal wires to each other or corresponding ones of the ground conductors to each other. The resin body includes a rigid portion and a flexible portion, the flexible portion being bendable independently of the rigid portion. The ground conductors include at least one counter ground on or inside the resin body, facing at least one of the signal wires in a stacking direction in which the plurality of resin layers are stacked, and overlapping the at least one of the plurality of signal wires in plan view in the stacking direction. The at least one counter ground conductor is made of a graphite sheet including main surfaces and end surfaces covered with a conductor layer. The graphite sheet extends over the rigid portion and the flexible portion in plan view in the stacking direction.

An electronic-component-equipped multilayer board according to a preferred embodiment of the present invention includes a resin body including a stack of a plurality of resin layers each being made from thermoplastic resin, a plurality of signal wires and a plurality of ground conductors each on or inside the resin body, at least one via conductor extending through at least one of the resin layers in a thickness direction and connecting corresponding ones of the signal wires to each other or corresponding ones of the ground conductors to each other, and an electronic component on an outer surface of the resin body. The resin body includes a rigid portion and a flexible portion, the rigid portion including the electronic component, the flexible portion being bendable independently of the rigid portion. The ground conductors include at least one counter ground conductor on or inside the resin body, facing at least one of the signal wires in a stacking direction in which the plurality of resin layers are stacked, and overlapping the at least one of the signal wires in plan view in the stacking direction. The at least one counter ground conductor is made of a graphite sheet including main surfaces and end surfaces covered with a conductor layer. The graphite sheet extends over the rigid portion and the flexible portion in plan view in the stacking direction.

An electronic-component-equipped multilayer board according to a preferred embodiment of the present invention includes a resin body including a stack of a plurality of resin layers each being made from thermoplastic resin, a plurality of signal wires and a plurality of ground conductors each on or inside the resin body, at least one via conductor extending through at least one of the resin layers in a thickness direction and connecting corresponding ones of the signal wires to each other or corresponding ones of the ground conductors to each other, and an electronic component inside the resin body. The resin body includes a rigid portion and a flexible portion, the rigid portion including the electronic component, the flexible portion being bendable independently of the rigid portion. The ground conductors include at least one counter ground conductor on or inside the resin body, facing at least one of the signal wires in a stacking direction in which the plurality of resin layers are stacked, and overlapping the at least one of the signal wires in plan view in the stacking direction. The at least one counter ground conductor is made of a graphite sheet including main surfaces and end surfaces covered with a conductor layer. The graphite sheet extends over the rigid portion and the flexible portion in plan view in the stacking direction.

According to preferred embodiments of the present invention, the multilayer circuit boards each obtain highly reliable connection between the via conductors and the ground conductors.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 schematically illustrates a section of an exemplary multilayer circuit board according to a first preferred embodiment of the present invention.

FIG. 2 schematically illustrates a section of an exemplary electronic-component-equipped multilayer board according to the first preferred embodiment of the present invention.

FIG. 3 is a plan view of the electronic-component-equipped multilayer board illustrated in FIG. 2, illustrating a layer of a graphite sheet and the topmost layer carrying an electronic component.

FIG. 4 schematically illustrates a section of an exemplary electronic-component-equipped multilayer board according to a second preferred embodiment of the present invention.

FIG. 5 schematically illustrates a section of an exemplary electronic-component-equipped multilayer board according to a third preferred embodiment of the present invention.

FIG. 6 schematically illustrates a section of an exemplary electronic-component-equipped multilayer board according to a fourth preferred embodiment of the present invention.

FIG. 7 is a plan view of the electronic-component-equipped multilayer board illustrated in FIG. 6, illustrating a layer of a graphite sheet and the topmost layer carrying an electronic component.

### DETAILED DESCRIPTION OF THE PREFERRED EMBODIMENTS

Multilayer circuit boards and electronic-component-equipped multilayer boards according to preferred embodiments of the present invention will be described below with reference to the drawings.

The present invention is not limited to the preferred embodiments described below and may be changed in any way without departing from the scope of the present invention. Any combination of two or more preferred embodiments among those to be described below is also encompassed by the present invention.

The following preferred embodiments are only exemplary. Any replacement or combination of some of the configurations between different preferred embodiments is acceptable. In second and subsequent preferred embodiments, redundant description of elements that are common to the first preferred embodiment is omitted, and only the differences from the first preferred embodiment will be described. In particular, the same or similar advantageous effects produced by the same or similar configurations are not described for every preferred embodiment.

### First Preferred Embodiment

According to a first preferred embodiment of the present invention, an electronic component is provided on an outer surface of a resin body included in a multilayer circuit board. Furthermore, according to the first preferred embodiment of the present invention, the number of resin layers stacked in a rigid portion is greater than the number of resin layers stacked in a flexible portion.

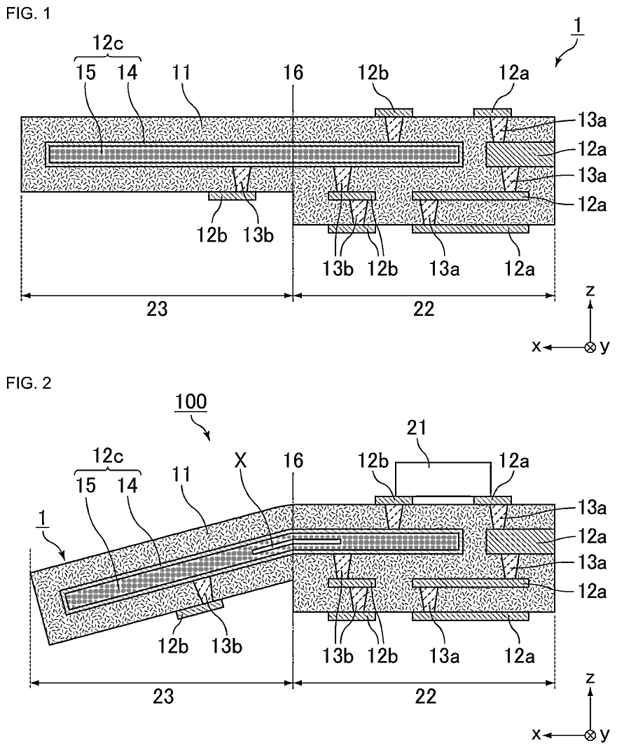

FIG. 1 schematically illustrates a section of an exemplary multilayer circuit board according to the first preferred embodiment of the present invention.

Referring to FIG. 1, a multilayer circuit board 1 includes a resin body 11, a plurality of signal wires 12a, a plurality of ground conductors 12b, via conductors 13a, and via conductors 13b. The signal wires 12a and the ground conductors 12b are each provided on or inside the resin body 11. The via conductors 13a each connect corresponding ones of the signal wires 12a to each other. The via conductors 13b each connect corresponding ones of the ground conductors 12b to each other.

In the multilayer circuit board 1 illustrated in FIG. 1, the longitudinal direction is defined as the x-axis direction, the width direction is defined as the y-axis direction, and a stacking direction is defined as the z-axis direction. The longitudinal direction, the width direction, and the stacking direction are orthogonal or substantially orthogonal to one another. The thicknesses of the individual elements illustrated in FIG. 1 are appropriately changed for clarity and simplicity of the drawing and are not to scale. This also applies to the other drawings.

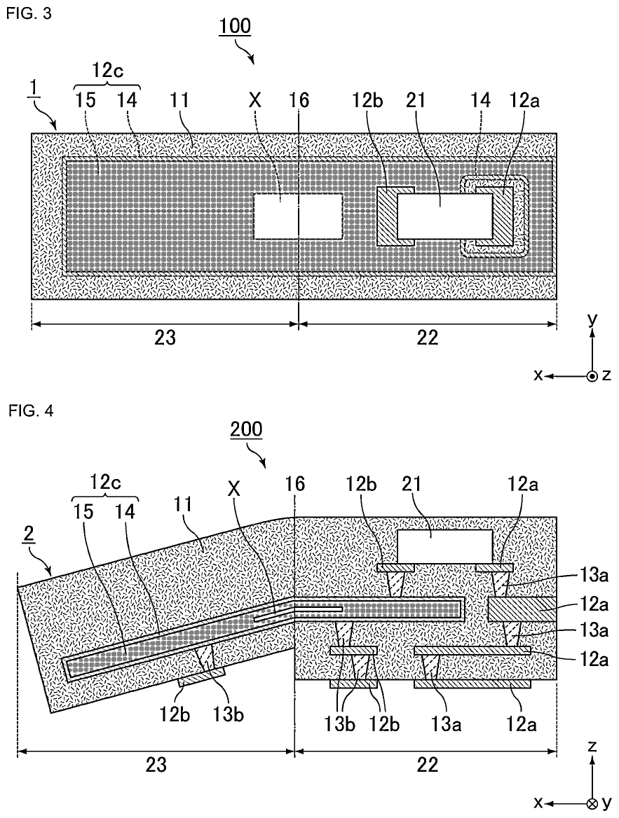

FIG. 2 schematically illustrates a section of an exemplary electronic-component-equipped multilayer board according to the first preferred embodiment of the present invention. FIG. 3 is a plan view of the electronic-component-equipped multilayer board illustrated in FIG. 2, illustrating a layer of a graphite sheet and the topmost layer carrying an electronic component.

Referring to FIGS. 2 and 3, an electronic-component-equipped multilayer board 100 includes the multilayer circuit board 1 and an electronic component 21. The electronic component 21 is provided on an outer surface of the multilayer circuit board 1. In the electronic-component-equipped multilayer board 100 illustrated in FIG. 2, the multilayer circuit board 1 illustrated in FIG. 1 is bent, with the electronic component 21 provided thereon.

The resin body 11 is a multilayer body including a plurality of resin layers. Specifically, the resin body 11 is formed by stacking a plurality of resin sheets in the z-axis direction and bonding the resin sheets to one another under pressure. Therefore, the interfaces between the resin layers may be invisible.

The signal wires 12a are each provided on a main surface of any of the resin sheets and are therefore each located on an outer surface of the resin body 11 or inside the resin body 11. Specifically, any signal wire 12a provided on a main surface of the topmost or bottommost one of the resin sheets in the multilayer body is located on an outer surface of the resin body 11. On the other hand, any signal wire 12a provided on a main surface of any of the resin sheets other than the topmost and bottommost ones in the multilayer body is located inside the resin body 11. The signal wires 12a extend in the x-axis direction and in the y-axis direction. Similarly, the ground conductors 12b are each provided on a main surface of any of the resin sheets and are therefore each located on an outer surface of the resin body 11 or inside the resin body 11. Specifically, any ground conductor 12b provided on a main surface of the topmost or bottommost one of the resin sheets in the multilayer body is located on an outer surface of the resin body 11. On the other hand, any ground conductor 12b provided on a main surface of any of the resin sheets other than the topmost and bottommost ones in the multilayer body is located inside the resin body 11. The ground conductors 12b extend in the x-axis direction and in the y-axis direction. The signal wires 12a and the ground conductors 12b define and function as wiring patterns in the multilayer circuit board 1.

The via conductors 13a and 13b each extend through at least one of the resin layers in the thickness direction. The two ends of each of the via conductors 13a are connected to corresponding ones of the signal wires 12a. The two ends of each of the via conductors 13b are connected to corresponding ones of the ground conductors 12b.

The ground conductors 12b include a counter ground conductor 12c. The counter ground conductor 12c is provided on or inside the resin body 11 in such a manner as to face toward any of the signal wires 12a in the z-axis direction coinciding with the stacking direction and to overlap the signal wire 12a in plan view in the z-axis direction coinciding with the stacking direction. The counter ground conductor 12c may be a single counter ground conductor 12c or one of two or more counter ground conductors 12c.

The counter ground conductor 12c may be provided inside the resin body 11 or on an outer surface of the resin body 11. The counter ground conductor 12c may have the same or substantially the same thickness as or a different thickness from the other ground conductors 12b. The counter ground conductor 12c may be thicker or thinner than the other ground conductors 12b.

At least one of such counter ground conductors 12c is made of a graphite sheet 15 whose main surfaces and end surfaces are covered with a conductor layer 14. The conductor layer 14 and the graphite sheet 15 may be joined to each other by, for example, thermocompression bonding such as hot pressing or film deposition such as sputtering, vapor deposition, or plating.

Since the counter ground conductor 12c is used as a ground conductor 12b, any of the via conductors 13b may be connected to the conductor layer 14 provided over the surfaces of the graphite sheet 15.

As illustrated in FIGS. 1, 2, and 3, the resin body 11 includes a rigid portion 22 and a flexible portion 23. The flexible portion 23 is bendable at an interface 16 defined between the rigid portion 22 and the flexible portion 23. The flexible portion 23 is flexible and is bendable independently of the rigid portion 22. The rigid portion 22 does not necessarily need to be highly rigid. It does not matter how rigid the rigid portion 22 is. The rigid portion 22 is not supposed to be bent. Comparing the rigid portion 22 and the flexible portion 23, the rigid portion 22 does not necessarily need to have higher rigidity than the flexible portion 23.

As illustrated in FIGS. 2 and 3, the rigid portion 22 is provided with the electronic component 21, whereas the flexible portion 23 is provided with no electronic component 21. The density of the wiring patterns in the rigid portion 22 is higher than in the flexible portion 23. The rigid portion 22 may include a reinforcing plate.

FIG. 2 illustrates a state where the electronic component 21 is provided on the upper surface (a surface on the positive side in the z-axis direction) of the resin body 11 and the flexible portion 23 is bent toward the negative side in the z-axis direction. However, on which surface the electronic component 21 is provided and in which direction the flexible portion 23 is bent are not specifically limited.

In plan view in the z-axis direction coinciding with the stacking direction as illustrated in FIG. 3, the graphite sheet 15 extends over the rigid portion 22 and the flexible portion 23. Accordingly, the interface 16 between the rigid portion 22 and the flexible portion 23 extends across the graphite sheet 15.

When the board is bent at the interface 16 between the rigid portion 22 and the flexible portion 23, any of the ground conductors 12b that is directly below the point of load application is subjected to a compressive stress at a surface thereof from which the load is applied and to a tensile stress at the opposite surface thereof. Some of the via conductors 13b that are located close to the point of load application and connected to the above ground conductor 12b are rigid. Therefore, the stress tends to concentrate on relevant connection interfaces. In the case illustrated in FIG. 2 where the ground conductor 12b located directly below the point of load application is the counter ground conductor 12c, since the graphite sheet 15 in the counter ground conductor 12c includes layers that are bonded to one another with a weak force, such as intermolecular force, the graphite sheet 15 is supposed to cause layer separation prior to the other elements and thus releases the bending stress. Therefore, it is considered that even if the board is bent, the stress concentrated on the connection interfaces between the ground conductor 12b and the via conductors 13b is released, such that reliability at the connections is increased. FIGS. 2 and 3 illustrate such a separated region X produced in the graphite sheet 15. In actuality, the separated region X may be invisible.

If such layer separation of the graphite sheet 15 progresses to an end portion of the graphite sheet 15, the board may be divided at the graphite sheet 15 into an upper portion and a lower portion. In view of such a situation, the graphite sheet 15 is covered with the conductor layer 14 provided over not only the main surfaces thereof but also the end surfaces thereof. Thus, the progress of cracking in the graphite sheet 15 is reduced or prevented, such that the division of the board is prevented.

Furthermore, unlike the resin multilayer board disclosed by Japanese Unexamined Patent Application Publication No. 2014-222721, there is no limitation on the shape of the conductor patterns. Therefore, flexible pattern formation is enabled.

In this specification, a state where the interface 16 between the rigid portion 22 and the flexible portion 23 in plan view in the stacking direction intersects two opposite sides of the graphite sheet 15 is defined as a state where the interface 16 between the rigid portion 22 and the flexible portion 23 extends across the graphite sheet 15. The angle at which the interface 16 between the rigid portion 22 and the flexible portion 23 intersects two opposite sides of the graphite sheet 15 is not specifically limited. The interface 16 between the rigid portion 22 and the flexible portion 23 may be either orthogonal or substantially orthogonal to two opposite sides of the graphite sheet 15 or not.

In the multilayer circuit board 1 illustrated in FIG. 1, the number of resin layers stacked in the rigid portion 22 is greater than the number of resin layers stacked in the flexible portion 23. Making the number of resin layers stacked in the rigid portion 22 greater than in the flexible portion 23 further reduces the bending stress that acts on elements around the electronic component 21.

The resin layers of the resin body 11 are made from thermoplastic resin. Examples of thermoplastic resin include liquid crystal polymer (LCP), polyimide resin (PI), polyether ether ketone resin (PEEK), and polyphenylene sulfide resin (PPS).

The resin layers of the resin body 11 each only need to have a thickness of, for example, about 10 μm or greater and 100 μm or smaller. The thickness of each of the resin layers of the resin body 11 may be, for example, about 25 μm or about 50 μm.

The material for the signal wires 12a and the ground conductors 12b may be, for example, copper (Cu), silver (Ag), aluminum (Al), stainless steel (SUS), nickel (Ni), or gold (Au), or may be an alloy of two or more metals selected from the foregoing ones. The signal wires 12a and the ground conductors 12b may preferably be made of a conductive foil, particularly preferably copper foil, for example.

The material for the via conductors 13a and 13b may be, for example, Cu, Ag, Al, SUS, Ni, or Au, or may be an alloy of two or more metals selected from the foregoing ones. The via conductors 13a and 13b may be formed by providing via holes in the resin body 11 and filling the via holes by, for example, electroless plating or filling the via holes with conductive paste by screen printing or the like. The conductive paste may preferably include at least one of Cu, Ag, and Ni and at least one of Sn, Bi, and Zn.

The material for the conductor layer 14 may be, for example, Cu, Ag, Al, SUS, Ni, or Au, or may be an alloy of two or more metals selected from the foregoing ones.

Denoting the thickness of the conductor layer 14 as δ, the thickness δ of the conductor layer 14 may be calculated by Expression (1) below, which expresses the depth of penetration of the electric current at a frequency handleable by the multilayer circuit board 1. The thickness δ only needs to be greater than the depth of penetration.

δ=5.03√(ρ/μf) [cm] (1)

In Expression (1), ρ denotes the resistivity [μΩ·cm] of the conductor layer, μ denotes the relative magnetic permeability of the conductor layer, and f denotes the frequency [Hz] of the electric current flowing through the conductors in the multilayer circuit board.

Resistivity is measurable with, for example, Loresta GP from Mitsubishi Chemical Analytech Co., Ltd. while applying a constant current by a four-probe method.

The graphite sheet 15 is obtained by processing graphite into a sheet. The graphite sheet 15 may preferably be, for example, a graphene sheet including graphene layers that are stacked with van der Waals forces and each have a planar structure in which a plurality of carbon atoms are coupled to one another forming a hexagonal lattice. More preferably, the graphene sheet may include graphene layers stacked such that the planar direction (XY plane) of the graphene is orthogonal or substantially orthogonal to the thickness direction (Z-direction). In such a case, the graphite sheet has higher thermal conductivity in the planar direction than in the thickness direction.

The thickness of the graphite sheet 15 is not specifically limited but may preferably be about 10 μm or greater, and more preferably about 20 μm or greater, for example. On the other hand, the thickness of the graphite sheet 15 may preferably be about 200 μm or smaller, more preferably about 100 μm or smaller, and even more preferably about 80 μm or smaller, for example.

The thickness of the graphite sheet 15 is calculated as the average of thicknesses measured at any ten points.

The thermal conductivity of the graphite sheet 15 in the planar direction is not specifically limited but may preferably be about 700 W/mk or higher, more preferably about 1000 W/mk or higher, even more preferably about 1500 W/mk or higher, and particularly preferably about 1800 W/mk or higher, for example.

The thermal conductivity of the graphite sheet 15 in the planar direction is calculated by Expression (2) below:

A=α×d×Cp (2)

In Expression (2), A denotes the thermal conductivity of the graphite sheet, α denotes the thermal diffusivity of the graphite sheet, d denotes the density of the graphite sheet, and Cp denotes the specific heat capacity of the graphite sheet.

The thermal diffusivity of the graphite sheet is measured on a sample graphite sheet of a size of about 50 mm by about 50 mm in an atmosphere of about 25° C., with a thermal-diffusivity-measuring device (Thermowave Analyzer TA from BETHEL Co., Ltd., for example) based on laser spot periodic heating radiation thermometry.

The density of the graphite sheet is calculated by measuring the weight and thickness of a sample graphite sheet of a size of about 50 mm by about 50 mm and dividing the value of the measured weight by the volume calculated (about 50 mm×about 50 mm×thickness).

The specific heat capacity of the graphite sheet is measured with a differential scanning calorimeter (DSC Q2000 from TA Instruments, for example) while the temperature is raised from about 20° C. to about 260° C. at an increment of about 10° C./min.

The electrical conductivity of the graphite sheet 15 is not specifically limited but may preferably be about 7000 S/cm or higher, more preferably about 10,000 S/cm or higher, much more preferably about 13,000 S/cm or higher, and particularly preferably about 18,000 S/cm or higher, for example. On the other hand, the electrical conductivity of the graphite sheet may preferably be about 25,000 S/cm or lower, and more preferably about 20,000 S/cm or lower.

The electrical conductivity of the graphite sheet 15 is measurable with, for example, Loresta GP from Mitsubishi Chemical Analytech Co., Ltd. while applying a constant current by a four-probe method.

The density of the graphite sheet 15 is not specifically limited but may preferably be about 0.8 g/cm³ or higher, and more preferably about 1.8 g/cm³ or higher, for example. On the other hand, the density of the graphite sheet 15 may preferably be about 2.2 g/cm³ or lower, for example.

Exemplary commercial products for the graphite sheet 15 include Graphinity from KANEKA CORPORATION and PGS (registered trademark) from Panasonic Corporation.

In the electronic-component-equipped multilayer board 100 illustrated in FIGS. 2 and 3, the electronic component 21 is provided on an outer surface of the resin body 11. The electronic component 21 may be an active component or a passive component. Alternatively, the electronic component 21 may be a compound of an active component and a passive component. Examples of the active component include semiconductor devices such as a transistor, a diode, an IC, and an LSI. Examples of the passive component include chip-type components such as a resistor, a condenser, and an inductor, as well as a vibrating element and a filter.

The electronic component 21 may preferably be connected to the counter ground conductor 12c through a thermal via, which is not illustrated in FIG. 2. Particularly preferably, the electronic-component-equipped multilayer board 100 may include an active component used as the electronic component 21 and connected to the counter ground conductor 12c through a thermal via.

The multilayer circuit board according to the first preferred embodiment of the present invention may preferably be manufactured as follows, for example.

First, resin sheets are prepared, and conductive foil such as, for example, copper foil is pasted on main surfaces of the resin sheets. The resin sheets are formed from the above-described material, such as liquid crystal polymer, for example. Subsequently, signal wires 12a and ground conductors 12b are each formed on a corresponding one of the main surfaces of the resin sheets. Specifically, a resist is photolithographically provided over the conductive foil on each of the resin sheets so as to have the shape of a corresponding one of signal wires 12a and ground conductors 12b to be formed. Subsequently, etching is performed on the conductive foil to remove portions of the conductive foil that are not covered with the resist. Then, the resist is removed. Thus, signal wires 12a and ground conductors 12b are formed on relevant main surfaces of the resin sheets.

On the other hand, a graphite sheet 15 is prepared and is processed to be shaped as a counter ground conductor 12c. Specifically, a graphite sheet 15 is irradiated with a laser, such as, for example, one employing CO₂, UV, or a semiconductor, operating at any wavelength, such that unnecessary portions of the graphite sheet 15 are removed. The graphite sheet 15 obtained after the removal is degreased, and a conductor layer 14 is formed by electroplating over the main surfaces and end surfaces of the graphite sheet 15. Thus, a counter ground conductor 12c is obtained that is formed of the graphite sheet 15 whose main surfaces and end surfaces are covered with the conductor layer 14. Subsequently, a resin sheet is prepared, and the counter ground conductor 12c is pasted on a main surface of the resin sheet.

Then, a surface of each of the resin sheets that is opposite to the surface on which any of the signal wire 12a, the ground conductor 12b, and the counter ground conductor 12c is pasted is irradiated with a laser, such as, for example, one employing CO₂, UV, or a semiconductor, such that via holes are provided in the resin sheet. Furthermore, the via holes are filled with conductive paste by, for example, screen printing. Thus, via conductors 13a and 13b are formed.

After the via conductors 13a and 13b are formed, the plurality of resin sheets each including at least one of the signal wire 12a, the ground conductor 12b, and the counter ground conductor 12c are stacked and are thermally compressed to be bonded to one another. Thus, a multilayer circuit board 1 is obtained as illustrated in FIG. 1.

The multilayer circuit board 1 is deformable into a predetermined shape when pressurized after being heated at the point of bending-load application to a temperature at which the resin sheets thereof exert a thermoplastic characteristic.

Then, an electronic component 21 is provided on an outer surface of the multilayer circuit board 1. Thus, an electronic-component-equipped multilayer board 100 is obtained.

### Second Preferred Embodiment

According to a second preferred embodiment of the present invention, the electronic component is not provided on an outer surface of the resin body included in the multilayer circuit board, but is provided inside the resin body. The other details may be the same or substantially the same as in the first preferred embodiment of the present invention.

FIG. 4 schematically illustrates a section of an exemplary electronic-component-equipped multilayer board according to the second preferred embodiment of the present invention.

Referring to FIG. 4, an electronic-component-equipped multilayer board 200 includes a multilayer circuit board 2 and an electronic component 21. The electronic component 21 is provided inside the multilayer circuit board 2. The electronic component 21 is provided inside the resin body 11. The other details are the same or substantially the same as those of the electronic-component-equipped multilayer board 100 illustrated in FIG. 2.

The second preferred embodiment of the present invention provides the same or substantially the same advantageous effects as the first preferred embodiment of the present invention.

### Third Preferred Embodiment

According to a third preferred embodiment of the present invention, the number of resin layers stacked in the rigid portion is smaller than or equal to the number of resin layers stacked in the flexible portion. The other details may be the same or substantially the same as in the first or second preferred embodiment of the present invention.

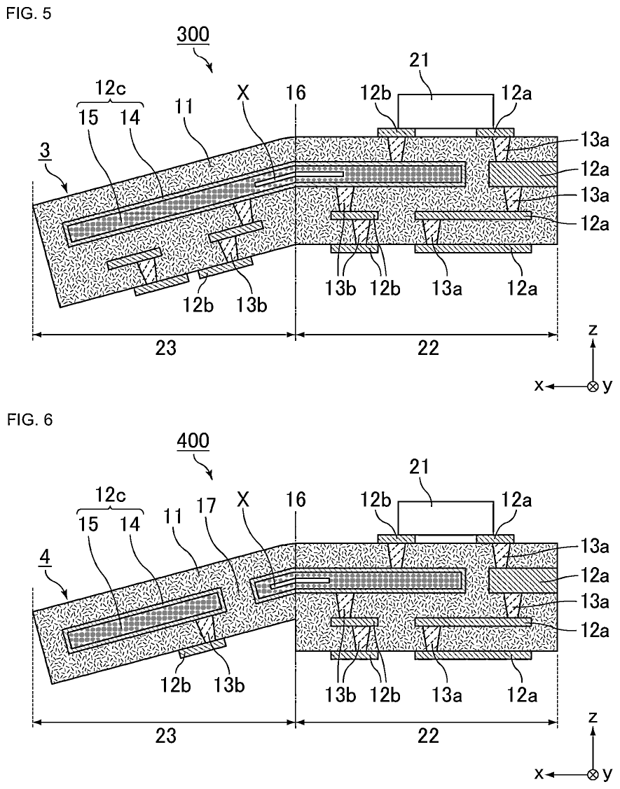

FIG. 5 schematically illustrates a section of an exemplary electronic-component-equipped multilayer board according to the third preferred embodiment of the present invention.

Referring to FIG. 5, an electronic-component-equipped multilayer board 300 includes a multilayer circuit board 3 and an electronic component 21. The electronic component 21 is provided on an outer surface of the multilayer circuit board 3. The electronic component 21 is provided on an outer surface of the resin body 11.

In the multilayer circuit board 3 illustrated in FIG. 5, the number of resin layers stacked in the rigid portion 22 is equal to the number of resin layers stacked in the flexible portion 23. The number of resin layers stacked in the rigid portion 22 may be smaller than the number of resin layers stacked in the flexible portion 23. The other details are the same or substantially the same as those of the electronic-component-equipped multilayer board 100 illustrated in FIG. 2. The other details may be the same or substantially the same as those of the electronic-component-equipped multilayer board 200 illustrated in FIG. 4.

In a typical flexible multilayer circuit board, the number of resin layers stacked in the rigid portion 22 tends to be greater than the number of resin layers stacked in the flexible portion 23, in order to reduce the influence of the bending stress upon elements around the electronic component 21. However, as described in the first preferred embodiment of the present invention, with the counter ground conductor 12c configured to reduce the bending stress that acts on elements around the electronic component 21, the number of resin layers stacked in the rigid portion 22 does not necessarily need to be greater than the number of resin layers stacked in the flexible portion 23. That is, the number of resin layers stacked in the rigid portion 22 may be equal to or smaller than the number of resin layers stacked in the flexible portion 23.

### Fourth Preferred Embodiment

According to a fourth preferred embodiment of the present invention, the graphite sheet includes at least one hole extending therethrough in the thickness direction and arranged on a line parallel or substantially parallel to the interface between the rigid portion and the flexible portion. Furthermore, the inner peripheral surface of the hole is covered with a conductor layer. The other details may be the same or substantially the same as in the first, second, or third preferred embodiment of the present invention.

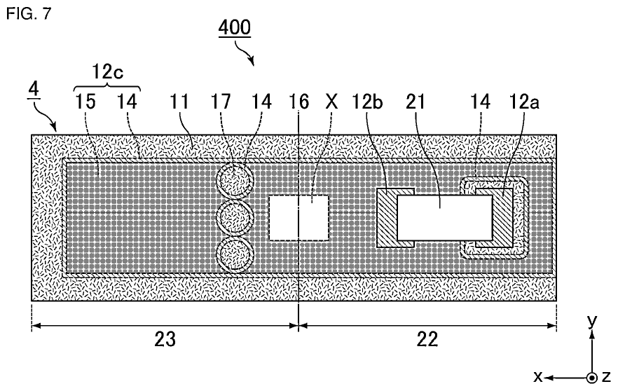

FIG. 6 schematically illustrates a section of an exemplary electronic-component-equipped multilayer board according to the fourth preferred embodiment of the present invention. FIG. 7 is a plan view of the electronic-component-equipped multilayer board illustrated in FIG. 6, illustrating a layer of a graphite sheet and the topmost layer on which an electronic component is provided.

Referring to FIGS. 6 and 7, an electronic-component-equipped multilayer board 400 includes a multilayer circuit board 4 and an electronic component 21. The electronic component 21 is provided on an outer surface of the multilayer circuit board 4. The electronic component 21 is provided on an outer surface of the resin body 11.

In the multilayer circuit board 4 illustrated in FIGS. 6 and 7, the graphite sheet 15 includes at least one hole 17. The hole 17 extends through the graphite sheet 15 in the thickness direction and is arranged on a line parallel or substantially parallel to the interface 16 between the rigid portion 22 and the flexible portion 23. The inner peripheral surface of the hole 17 is covered with a conductor layer 14. The other details are the same or substantially the same as those of the electronic-component-equipped multilayer board 100 illustrated in FIG. 2. The other details may be the same or substantially the same as those of the electronic-component-equipped multilayer board 200 illustrated in FIG. 4 or the electronic-component-equipped multilayer board 300 illustrated in FIG. 5.

The inner peripheral surface of the hole 17 is covered with the conductor layer 14. A resin layer may be provided thereinside. The hole 17 may be filled with a resin layer. Alternatively, a via conductor 13a for a signal wire 12a may be provided in the hole 17 while being kept out of contact with the conductor layer 14, which is provided over the graphite sheet 15, by a resin layer interposed therebetween. As another alternative, the hole 17 may be filled with the conductor layer 14, with no resin layer thereinside.

The graphite sheet 15 has a high thermal conductivity. However, the separated region X directly below the point of bending-load application includes an air gap defining and functioning as a heat-insulating layer. Consequently, the thermal conductivity in the thickness direction is deteriorated. According to the fourth preferred embodiment of the present invention, since the graphite sheet 15 includes the hole 17 extending therethrough in the thickness direction, the progress of the separation is reduced or prevented. Thus, while the thermal conductivity of the graphite sheet 15 is maintained, the deterioration at the connection between the via conductor 13b and the ground conductor 12b is prevented.

In this specification, a state where the shortest distance from the interface 16 between the rigid portion 22 and the flexible portion 23 to the centers of the holes 17 in plan view in the stacking direction is uniform is defined as a state where the holes 17 are arranged on a line parallel or substantially parallel to the interface 16 between the rigid portion 22 and the flexible portion 23. The shortest distance from the interface 16 between the rigid portion 22 and the flexible portion 23 to the centers of the holes 17 does not necessarily need to be strictly uniform and may fall within a tolerance of, for example, about 5% or smaller.

The sectional shape of the hole 17 is not specifically limited and may be, for example, a circle, an ellipse, or a polygon. If the graphite sheet 15 includes a plurality of holes 17, the holes 17 may have the same sectional shape or different sectional shapes. The size, interval, number, and any other factors of the hole 17 are not specifically limited.

The hole 17 may be provided on only one side or on each of two sides relative to the interface 16 between the rigid portion 22 and the flexible portion 23. If the hole 17 is provided on each of two sides relative to the interface 16 between the rigid portion 22 and the flexible portion 23, the sectional shape, size, interval, number, and any other factors of the holes 17 may be the same or different.

### Other Preferred Embodiments

The multilayer circuit board according to the present invention is not limited to the above-described preferred embodiments as long as the multilayer circuit board includes at least one counter ground conductor made of a graphite sheet covered with a conductor layer, and the graphite sheet extends over a rigid portion and a flexible portion in plan view in the stacking direction. That is, the configuration, the manufacturing conditions, and any other factors of the multilayer circuit board can be applied or modified in various ways within the scope of the present invention. Similarly, the electronic-component-equipped multilayer board can be applied and modified in various ways within the scope of the present invention.

For example, an electronic-component-equipped multilayer board according to a preferred embodiment of the present invention may include both an electronic component provided on an outer surface of the multilayer circuit board and an electronic component provided inside the multilayer circuit board.

While the above preferred embodiments each relates to a case where the electronic component 21 is a cuboid with electrodes thereof provided at two ends of the cuboid, the arrangement of the electrodes of the electronic component 21 is not limited to the above. The electronic component 21 may be provided with a plurality of electrodes, for example, as with an LGA (land grid array) or an IC.

A multilayer circuit board according to a preferred embodiment of the present invention may include two or more counter ground conductors. In such a case, at least one of the counter ground conductors only needs to be made of a graphite sheet covered with a conductor layer. The remaining counter ground conductors may be made of, for example, the material for the ground conductors other than the counter ground conductors. A multilayer circuit board according to a preferred embodiment of the present invention may include a graphite sheet that is not covered with a conductor layer.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multilayer circuit board comprising:
a resin body including a stack of a plurality of resin layers each being made from thermoplastic resin;
a plurality of signal wires and a plurality of ground conductors on or inside the resin body; and
at least one via conductor extending through at least one of the plurality of resin layers in a thickness direction and connecting corresponding ones of the signal wires to each other or corresponding ones of the ground conductors to each other; wherein
the resin body includes a rigid portion and a flexible portion, the flexible portion being bendable independently of the rigid portion;
the plurality of ground conductors include at least one counter ground conductor on or inside the resin body, facing at least one of the plurality of signal wires in a stacking direction in which the resin layers are stacked, and overlapping the at least one of the plurality of signal wires in plan view in the stacking direction;
the at least one counter ground conductor is made of a graphite sheet including main surfaces and end surfaces covered with a conductor layer; and
the graphite sheet extends over the rigid portion and the flexible portion in plan view in the stacking direction.

2. The multilayer circuit board according to claim 1, wherein a number of the plurality of resin layers stacked in the rigid portion is smaller than a number of the plurality of resin layers stacked in the flexible portion.

3. The multilayer circuit board according to claim 1, wherein
the graphite sheet includes at least one hole extending through the graphite sheet in the thickness direction and located on a line parallel or substantially parallel to an interface between the rigid portion and the flexible portion; and
an inner peripheral surface of the hole is covered with the conductor layer.

4. The multilayer circuit board according to claim 1, wherein a number of the plurality of resin layers stacked in the rigid portion is equal to a number of the plurality of resin layers stacked in the flexible portion.

5. The multilayer circuit board according to claim 1, wherein the resin body is bent at an interface between the rigid portion and the flexible portion.

6. The multilayer circuit board according to claim 1, wherein the thermoplastic resin includes at least one of liquid crystal polymer, polyimide resin, polyether ether ketone resin, or polyphenylene sulfide resin.

7. The multilayer circuit board according to claim 1, wherein a thickness of each of the plurality of resin layers is about 10 μm or greater and 100 μm or smaller.

8. An electronic-component-equipped multilayer board comprising:
a resin body including a stack of a plurality of resin layers each being made from thermoplastic resin;
a plurality of signal wires and a plurality of ground conductors on or inside the resin body;
at least one via conductor extending through at least one of the plurality of resin layers in a thickness direction and connecting corresponding ones of the signal wires to each other or corresponding ones of the ground conductors to each other; and
an electronic component on an outer surface of the resin body; wherein
the resin body includes a rigid portion and a flexible portion, the rigid portion including the electronic component, the flexible portion being bendable independently of the rigid portion;
the ground conductors include at least one counter ground conductor on or inside the resin body, facing at least one of the plurality of signal wires in a stacking direction in which the resin layers are stacked, and overlapping the at least one of the plurality of signal wires in plan view in the stacking direction;
at least one of the counter ground conductors is made of a graphite sheet including main surfaces and end surfaces covered with a conductor layer; and
the graphite sheet extends over the rigid portion and the flexible portion in plan view in the stacking direction.

9. The electronic-component-equipped multilayer board according to claim 8, wherein a number of the plurality of resin layers stacked in the rigid portion is smaller than a number of the resin layers stacked in the flexible portion.

10. The electronic-component-equipped multilayer board according to claim 8, wherein
the graphite sheet includes at least one hole extending through the graphite sheet in the thickness direction and located on a line parallel or substantially parallel to an interface between the rigid portion and the flexible portion; and
an inner peripheral surface of the hole is covered with the conductor layer.

11. The electronic-component-equipped multilayer board according to claim 8, wherein a number of the plurality of resin layers stacked in the rigid portion is equal to a number of the plurality of resin layers stacked in the flexible portion.

12. The electronic-component-equipped multilayer board according to claim 8, wherein the resin body is bent at an interface between the rigid portion and the flexible portion.

13. The electronic-component-equipped multilayer board according to claim 8, wherein the thermoplastic resin includes at least one of liquid crystal polymer, polyimide resin, polyether ether ketone resin, or polyphenylene sulfide resin.

14. The electronic-component-equipped multilayer board according to claim 8, wherein a thickness of each of the plurality of resin layers is about 10 μm or greater and 100 μm or smaller.

15. An electronic-component-equipped multilayer board comprising:
a resin body including a stack of a plurality of resin layers each being made from thermoplastic resin;
a plurality of signal wires and a plurality of ground conductors on or inside the resin body;
at least one via conductor extending through at least one of the plurality of resin layers in a thickness direction and connecting corresponding ones of the signal wires to each other or corresponding ones of the ground conductors to each other; and
an electronic component inside the resin body; wherein
the resin body includes a rigid portion and a flexible portion, the rigid portion including the electronic component, the flexible portion being bendable independently of the rigid portion;
the ground conductors include at least one counter ground conductor on or inside the resin body, facing at least one of the signal wires in a stacking direction in which the plurality of resin layers are stacked, and overlapping the at least one of the plurality of signal wire in plan view in the stacking direction;
the at least one counter ground conductor is made of a graphite sheet including main surfaces and end surfaces covered with a conductor layer; and
the graphite sheet extends over the rigid portion and the flexible portion in plan view in the stacking direction.

16. The electronic-component-equipped multilayer board according to claim 15, wherein a number of the plurality of resin layers stacked in the rigid portion is smaller than a number of the resin layers stacked in the flexible portion.

17. The electronic-component-equipped multilayer board according to claim 15, wherein
the graphite sheet includes at least one hole extending through the graphite sheet in the thickness direction and arranged on a line parallel or substantially parallel to an interface between the rigid portion and the flexible portion; and
an inner peripheral surface of the hole is covered with the conductor layer.

18. The electronic-component-equipped multilayer board according to claim 15, wherein a number of the plurality of resin layers stacked in the rigid portion is equal to a number of the plurality of resin layers stacked in the flexible portion.

19. The electronic-component-equipped multilayer board according to claim 15, wherein the resin body is bent at an interface between the rigid portion and the flexible portion.

20. The electronic-component-equipped multilayer board according to claim 15, wherein the thermoplastic resin includes at least one of liquid crystal polymer, polyimide resin, polyether ether ketone resin, or polyphenylene sulfide resin.
